(19) United States
(12) Patent Application Publication
(10) Pub. No.: US 2006/0227505 A1
(43) Pub. Date: Oct. 12, 2006

(54) Air flow distribution adjusting mechanism for disk array apparatus

(76) Inventors: Kenichi Miyamoto, Odawara (JP); Yoshikatsu Kasahara, Ninomiya (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/172,888

(22) Filed: Jul. 5, 2005

(30) Foreign Application Priority Data
Apr. 6, 2005 (JP) 2005-109504

(51) Int. Cl. H05K 7/20

(52) U.S. Cl. 361/695

(57) ABSTRACT

An air flow distribution adjusting mechanism for a disk array apparatus adjusts the distribution of air flowing in a disk array apparatus carrying a plurality of canisters. This air flow distribution adjusting mechanism includes an air flow distribution adjusting sheet for covering empty canister slots, and a sheet expanded length adjusting mechanism for adjusting the expanded length of the air flow distribution adjusting sheet.

### CROSS-REFERENCE TO RELATED APPLICATION

This application relates to and claims priority from Japanese Patent Application No. 2005-109504, filed on Apr. 6, 2005, the entire disclosure of which is incorporated herein by reference.

### BACKGROUND

The present invention relates to an air flow distribution adjusting mechanism for a disk array apparatus.

In a disk array apparatuses including a plurality of disk drives disposed in an arrays, progress has been made in recent years in the high-density packaging of, for example, HDD units (canisters), various logical boards and power supply boxes. Also, power consumption and heat generation continue to increase. To deal with the increasing heat generation, fan capacity is getting larger and larger. However, because the high-density packaging of the disk array apparatus causes an increase in vent line resistance, a sufficient cooling effect can not be obtained at present. As a result of enlarging the fan capacity to compensate for cooling air weakened by the increased vent line resistance, noise and power consumption are becoming larger and larger under the present circumstances.

By the way, the number of the canisters, logical boards, and power supply boxes to be mounted on the disk array apparatus depends on specifications required by the customer using the disk array apparatus. Accordingly, the maximum number of canisters, logical boards, and power supply boxes is not necessarily mounted, and empty slots may be left. The air resistance of the empty slots is far smaller than that of the area where the canisters and so on are densely mounted with small spaces between them. Therefore, if an empty slot is left open, the cooling air flowing in the disk array apparatus concentrates in the empty slot, and therefore a sufficient cooling effect cannot be obtained.

Considering the above described circumstances, a method of mounting various kinds of dummy units in empty slots of the disk array apparatus is conventionally known as a method for adjusting the distribution of air flowing into the empty slots. For example, dummy canisters are mounted in the empty canister slots, and the empty logical board and power supply box slots are covered with dummy covers.

Meanwhile, the content of Japanese Patent Laid-open (Kokai) Publication No. 2002-117663 is known as a technique for attaching optical disk dummy covers to empty optical disk device slots.

### SUMMARY

In the disk array apparatus, when the capacity for the canisters, logical boards, and power supply boxes is very large and many empty slots are left depending on how the customer wants to use the disk array apparatus, a large number of dummy units need to be mounted in the empty slots. As a result, the following problems may arise.

The number of slots for mounting canisters is very large; for example, a maximum of 128 slots in a basic chassis, and a maximum of 256 slots in an expanded chassis. Moreover, the cost of manufacturing the dummy units and the man-hours required for mounting them in the disk array apparatus are considerable.

Furthermore, because the dummy unit is made of plastic or sheet metal, a big storage space is necessary to store a large number of dummy units. For example, a dummy canister is width 30 mm×height 130 mm×depth 120 mm. Accordingly, three or four cardboard boxes of the size of 300 mm×300 mm×450 mm are needed in order to store 256 dummy canisters.

Furthermore, for example, in a device testing prior to shipping of the products it is necessary to frequently put the canisters in and remove them from the slots. At the same time, the dummy canisters are also frequently put in and removed from the slots. Accordingly, considerable man-hours are required.

Furthermore, a dummy canister made of sheet metal is heavy and thereby affects earthquake resistance when mounted in the disk array apparatus. For example, when the dummy cover is mounted over the slots of the logical boards, the weight increases by about 10 kg per one disk array apparatus.

The present invention was devised considering the above problems. It is an object of the present invention to provide an air flow distribution adjusting mechanism for a disk array apparatus that can achieve effective cooling at low cost.

To solve the above problems, the air flow distribution adjusting mechanism according to the present invention adjusts the distribution of the air flowing in a disk array apparatus having a plurality of canisters. The air flow distribution adjusting mechanism includes an air flow distribution adjusting sheet for covering empty canister slots, and a sheet expanded length adjusting mechanism for adjusting the expanded length of the air flow distribution adjusting sheet. With this configuration, it is possible to cover the empty canister slots and to adjust the distribution of cooling air flowing in the device. Therefore, no dummy canisters are necessary, thereby realizing low cost.

It is desirable, for example, to form ventilation holes so that the air flows through the ventilation holes in the air volume equivalent to that of the air flowing between the canisters mounted in the empty slots. Because of the ventilation holes, it is possible to obtain the same cooling effect as that when dummy canisters are mounted in the empty slots.

For example, it is desirable to form the ventilation holes so that the distribution of the air flowing through the air flow distribution adjusting sheet becomes smaller in the area closer to the canisters. This configuration can equalize the distribution of the cooling air flowing through the air flow distribution adjusting sheet.

Moreover, for example, the air flow distribution adjusting mechanism may further include a locking mechanism for suppressing vibration of the air flow distribution adjusting sheet. This locking mechanism can suppress the generation of noise caused by the air flow distribution adjusting sheet suppressing.

Furthermore, for example, the air flow distribution adjusting sheet may be made of a conductive sheet. The use of a conductive sheet can improve the electromagnetic shielding effect of the disk array apparatus.

In another aspect of the invention, an air flow distribution adjusting mechanism for a disk array apparatus adjusts the distribution of the air flow in the disk array apparatus having a plurality of logical boards. This air flow distribution adjusting mechanism includes an air flow distribution adjusting sheet for covering empty logical board slots and a sheet expanded length adjusting mechanism for adjusting the expanded length of the air flow distribution adjusting sheet.

Moreover, in another aspect of the invention, an air flow distribution adjusting mechanism for a disk array apparatus adjusts the distribution of air flowing in the disk array apparatus having a plurality of power supply boxes. The air flow distribution adjusting mechanism includes an air flow distribution adjusting sheet for covering empty power supply box slots and a sheet expanded length adjusting mechanism for adjusting the expanded length of the air flow distribution adjusting sheet.

With the air flow distribution adjusting mechanism of the present invention, effective cooling can be achieved at low cost.

### DESCRIPTION OF THE DRAWINGS

FIG. 1 is an overall perspective view of a disk array apparatus according to an embodiment of this invention.

FIG. 2 is a perspective view of an HDD box.

FIG. 3 is a perspective view of a logical board box.

FIG. 4 is a perspective view of a power supply box.

FIG. 5 is a vertical sectional view of a disk array apparatus.

FIG. 6 is a schematic configuration diagram of an air flow distribution adjusting mechanism for an HDD box.

FIG. 7 is a detailed configuration diagram of an air flow distribution adjusting mechanism.

FIG. 8 is an explanatory diagram illustrating the distribution of air flowing through an air flow distribution adjusting mechanism.

FIG. 9 is an explanatory diagram illustrating the distribution of air flowing through the air flow distribution adjusting mechanism.

FIG. 10 is an explanatory diagram of a vibration preventing mechanism of the air flow distribution adjusting sheet.

FIG. 11 is an explanatory diagram of the vibration preventing mechanism of the air flow distribution adjusting sheet.

FIG. 12 is an explanatory diagram of the vibration preventing mechanism of the air low distribution adjusting sheet.

FIG. 13 is an explanatory diagram of the vibration preventing mechanism of the air flow distribution adjusting sheet.

FIG. 14 is an explanatory diagram of an embodiment of mounting the air flow distribution adjusting mechanism.

FIG. 15 is an explanatory diagram of another embodiment of mounting the air flow distribution adjusting mechanism.

FIG. 16 is a detailed configuration diagram of an air flow distribution adjusting mechanism.

FIG. 17 is a schematic configuration diagram of an air flow distribution adjusting mechanism for a logical board box.

FIG. 18 is a schematic configuration diagram of an air flow distribution adjusting mechanism for a power supply box.

### DETAILED DESCRIPTION OF THE INVENTION

Embodiments of this invention are described below in detail with reference to the attached drawings.

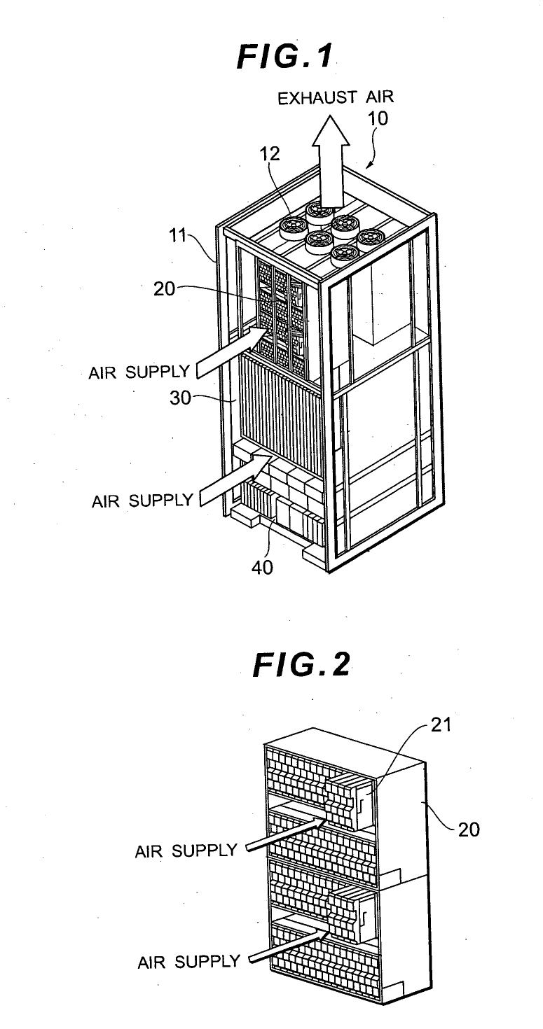

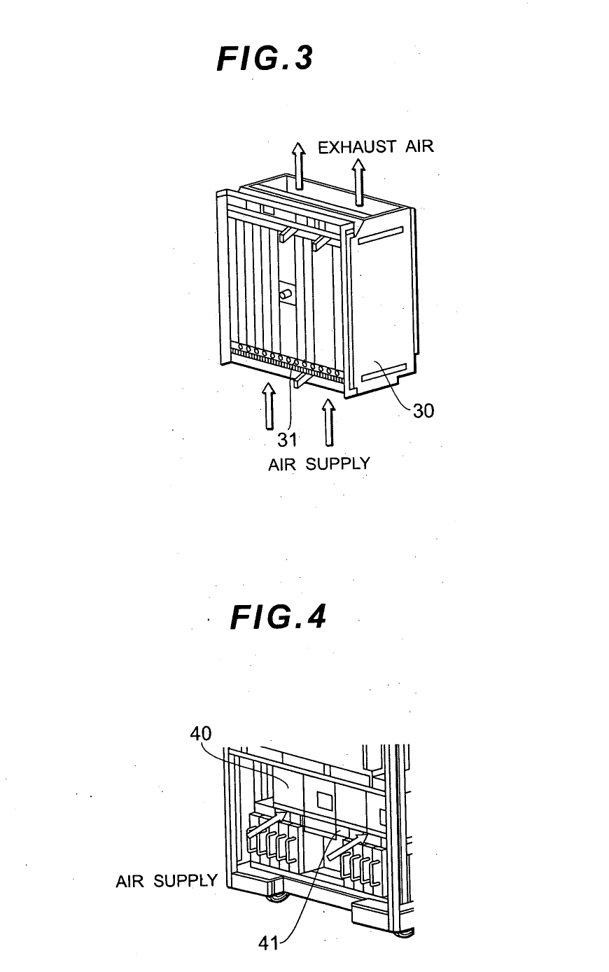

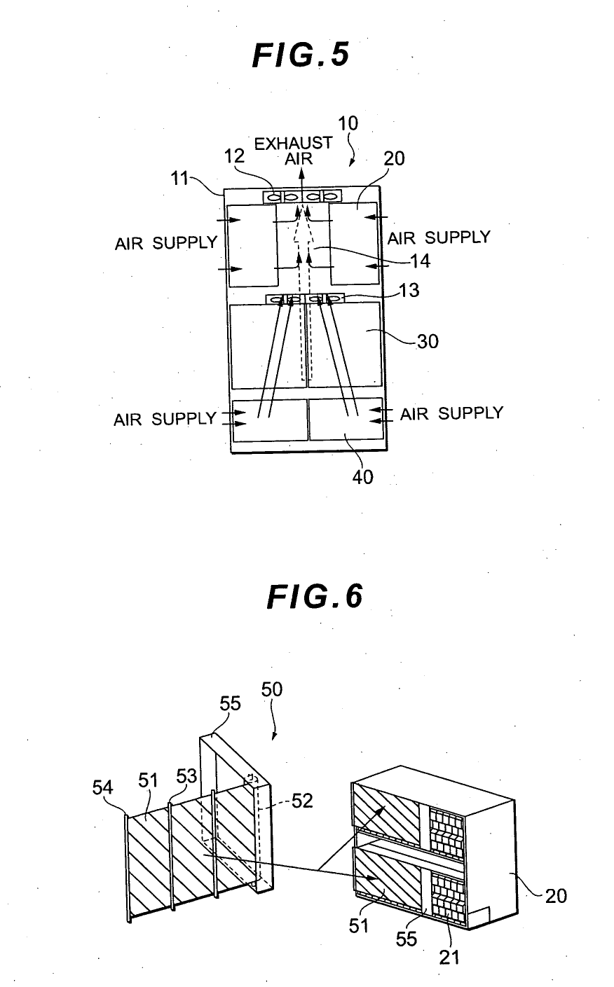

FIG. 1 shows an overall perspective view of a basic chassis of a disk array apparatus 10 according to an embodiment of this invention. FIG. 2 shows a perspective view of a HDD box 20. FIG. 3 shows a perspective view of a logical board box 30. FIG. 4 shows a perspective view of a power supply box 40. FIG. 5 shows a vertical sectional view of the disk array apparatus 10.

As shown in FIG. 1, the main components of the disk array apparatus 10 are the HDD box 20, the logical board box 30, and the power supply box 40. Each of the boxes 20, 30, and 40 is mounted on a rack in a frame 11 that forms the main framework of the disk array apparatus 10. The HDD box 20 is mounted on an upper rack of the frame 11, the logical board box 30 is mounted on a middle rack, and the power supply box 40 is mounted on a lower rack. By positioning the heavy power supply box 40 in the lower part of the disk array apparatus 10, the center of gravity of the entire disk array apparatus 10 is lowered.

As shown in FIG. 2, the HDD box 20 is used to carry a plurality of canisters 21 that store data to be input and output to/from a host system (not shown). The canisters 21 are connected to a back board of the HDD box 20 via a connector. One HDD box 20 can accommodate, for example, sixteen canisters 21 per single rack, and thirty-two canisters 21 in total. The disk array apparatus 10 can accommodate two HDD boxes on each of its front and back faces. Namely, the disk array apparatus 10 can accommodate four HDD boxes 20, that is, 128 canisters 21. Cooling air flowing toward the front face of the HDD box 20 passes into the inside of the HDD box 20 through slight gaps between the canisters 21 and draws the heat generated from the canisters 21. This cooling air passes through ventilation holes in the back board of the HDD box 20 and flows into an air duct 14 in the disk array apparatus 10. As shown in FIG. 5, the ceiling of the disk array apparatus 10 is provided with a plurality of fans 12 for forcedly cooling the inside of the disk array apparatus 10 by pull method. The fans 12 maintain negative pressure in the air duct 14 with their suction force. The cooling air that has passed through the back board of the HDD box 20 goes upward in the air duct 14 and is discharged out of the chassis via the fans 12. The speed of the cooling air flowing toward the front face of the HDD box 20 is, for example, about 0.4 m/s to 1.0 m/s, and that of the cooling air flowing between the canisters 21 is, for example, about 2.0 m/s.

As shown in FIG. 3, the logical board box 30 is used to carry a plurality of logical boards 31 that control the canisters 21. The top and bottom of the logical board box 30 are left open to ensure ventilation. As shown in FIG. 5, inside the disk array apparatus 10 fans 13 are installed above the area where the logical board box 30 is mounted, maintaining negative pressure inside the logical board box 30. The cooling air flowing inside the logical board box 30 goes upward while drawing the heat from the logical boards 31, and is sucked by the fans 13 into the air duct 14. The cooling air flowing into the air duct 14 is sucked again by the fans 12 and discharged out of the chassis. The speed of the cooling air flowing into the bottom of the logical board box 30 is, for example, about 0.4 m/s to 1.0 m/s, and that of the cooling air flowing around the logical board 31 is, for example, about 1.5 m/s to 2.0 m/s.

As shown in FIG. 4, the power supply box 40 is used to carry a power supply unit for supplying electric power to the canisters 21, the logical boards 31, and so on. Air intake openings 41 for taking in cooling air are formed below the area where the power supply box 40 is mounted. Ventilation is ensured inside the power supply box 40, while negative pressure is maintained by the suction force of the fans 12 and 13. The cooling air flowing through the air intake opening 41 into the power supply box 40 goes upward while drawing the heat generated inside the power supply box 40, passes through the top of the power supply box 40, and flows into the bottom of the logical box 30. The speed of the cooling air flowing into the air intake opening 41 is, for example, about 0.4 m/s to 1.0 m/s.

FIG. 6 shows the schematic configuration of an air flow distribution adjusting mechanism 50 according to this embodiment. The air flow distribution adjusting mechanism 50 includes an air flow distribution adjusting sheet 51, a sheet expanded length adjusting mechanism 52, a vibration preventing pole 53, a stopper 54, and a case 55, and functions as means for adjusting the distribution of the cooling air flowing into the empty slots in the HDD box 20. In the air flow distribution adjusting mechanism 50, the length of the air flow distribution adjusting sheet 51 can be adjusted by freely expanding and contracting the roll-up length of the air flow distribution adjusting sheet 51 in the sheet expanded length adjusting mechanism 52. As shown in FIG. 6, in the air flow distribution adjusting mechanism 50 the length of the air flow distribution adjusting sheet 51 is adjusted to about the same length as the width of an empty slot of the HDD box 20 in order to cover the empty slot. The air flow distribution adjusting sheet 51 is made of an air-permeable material and is capable of adjusting the distribution of the cooling air passing through the air flow distribution adjusting sheet 51 and flowing into the empty slot. The length of the air flow distribution adjusting sheet 51 is designed to be equal to or more than the width of the HDD box 20, and the width of the air flow distribution adjusting sheet 51 is designed to be equal to or more than the height of a canister 21.

The case 55 is a frame of the same size as a dummy canister and functions as means for fixing a shaft of the sheet expanded length adjusting mechanism 52. A force is always applied to the air flow distribution adjusting sheet 51 in the direction to which the sheet length contracts by the pulling force of the sheet expanded length adjusting mechanism 52. The stopper 54 is attached to an end of the air flow distribution adjusting sheet 51. By fixing the stopper 54 to the HDD box 20, the air flow distribution adjusting sheet 51 is prevented from being rolled in the contracting direction. The vibration preventing poles 53 hold the air flow distribution adjusting sheet 51 to the HDD box 20 at fixed intervals between them, and thus prevent the vibrating of the air flow distribution adjusting sheet 51 caused by wind pressure from the cooling air flowing through the air flow distribution adjusting sheet 51.

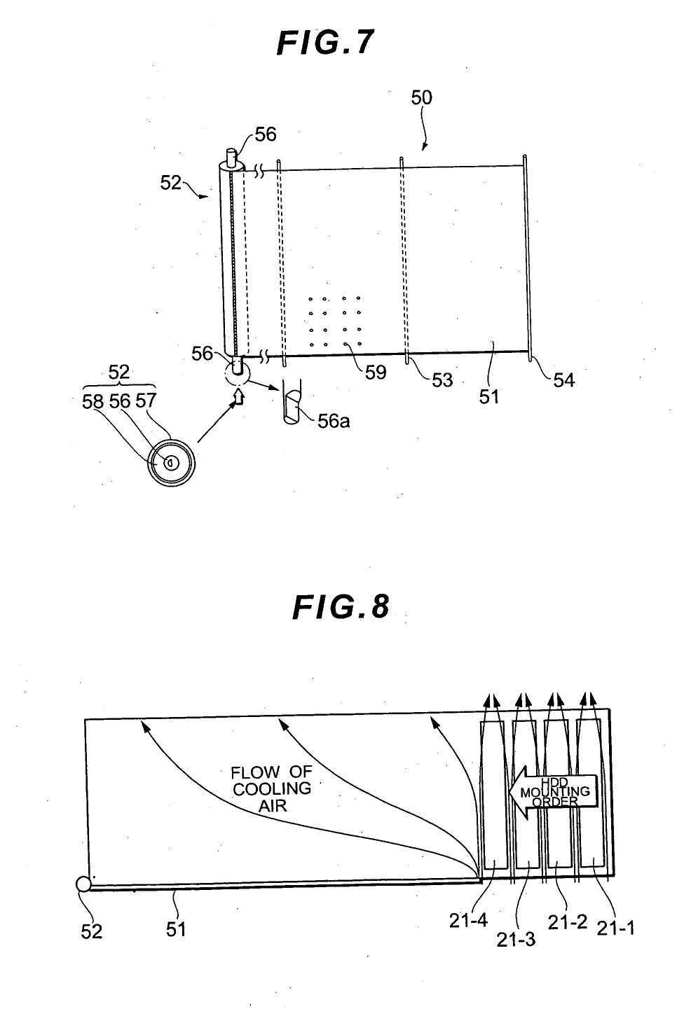

FIG. 7 shows the detailed configuration of the air flow distribution adjusting mechanism 50. The same reference numbers as used in FIG. 6 represent the same components, and a detailed description thereof is omitted. The sheet expanded length adjusting mechanism 52 includes a shaft 56, a sheet roll-up cylinder 57, and a spiral spring 58. The spiral spring 58 is inserted between the shaft 56 and the sheet roll-up cylinder 57, and is designed so that its resilience force caused by a rotation angle of the sheet roll-up cylinder 57 (the expanded or contracted length of the air flow distribution adjusting sheet 51) acts on the sheet expanded length adjusting mechanism 52. A notch 56a having a semicircular cross-section is formed at an end of the shaft 56, and is inserted to a shaft attachment hole (not shown) of the HDD box 20 so that the shaft 56 does not revolve and is fixed to the HDD box 20. The air flow distribution adjusting sheet 51 is adhesively attached to the surface of the sheet roll-up cylinder 57 with bonding means such as an adhesive agent. The air flow distribution adjusting sheet 51 has ventilation holes 59 distributed in a particular pattern as described below.

The disk array apparatus 10 is designed to satisfy the need for high-density packaging, and it is thereby preferable that the air flow distribution adjusting sheet 51 be of the required and sufficient size to be mounted on the disk array apparatus 10. For example, if—as the conditions for mounting the air flow distribution adjusting mechanism 50 on the disk array apparatus 10—(1) the outer diameter of the entire air flow distribution adjusting mechanism 50 is 25 mm or less; (2) the air flow distribution adjusting sheet 51 is as thin as possible; and (3) the length of the air flow distribution adjusting sheet 51 is approximately 450 mm, the thickness of the air flow distribution adjusting sheet 51 is preferably about 0.1 mm. Additionally, the diameter of the shaft 56 is preferably around 10 mm.

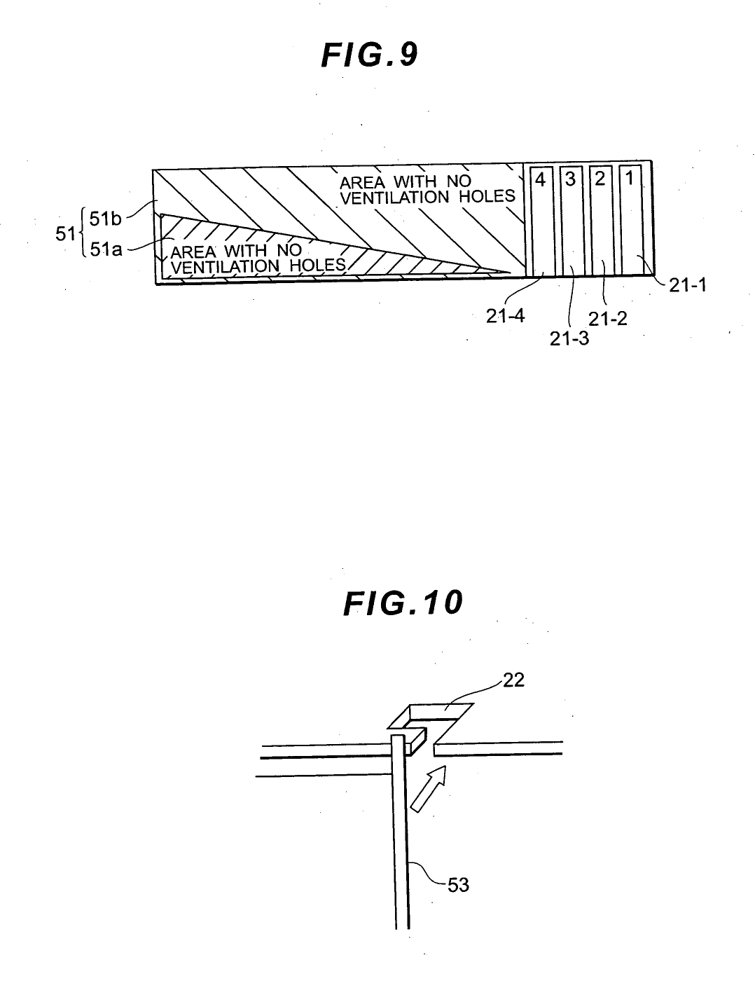

FIGS. 8 and 9 show the distribution of the air flowing through the air flow distribution adjusting mechanism 50. FIG. 8 is a schematic diagram showing the HDD box viewed from the top, and FIG. 9 is a schematic diagram showing the HDD box 20 viewed from the front. As described above, since the air resistance is small in an empty slot, the cooling air hardly flows through the gaps between the canisters 21 when the empty slot is left open, and can not sufficiently cool down the canisters 21. On the other hand, if the empty slot is sealed, the cooling air locally flows into location of the gaps between the canisters 21, increasing noise. To solve the above-described problem, the air flow distribution adjusting mechanism 50 adjusts the distribution of the cooling air passing through the air flow distribution adjusting sheet 51 to be almost equal to the cooling air flowing between the dummy canisters mounted in the empty slots.

The following explanation is given, assuming that the canisters 21 are mounted from the right to left of the HDD box 20. In the example shown in the FIGS. 8 and 9, the canisters are mounted in the order of 21-1, 21-2, 21-3, and then 21-4. As shown in FIG. 8, the volume of the cooling air is largest in the gap between the canister 21-4 that is mounted last and the air flow distribution adjusting sheet 51. Therefore, it is desirable to reduce the air flow volume (or air flow speed) of the cooling air in an area closer to the canister 21 and make larger the air flow volume (or air flow speed) of the cooling air in an area farther from the canister 21. As a result, the air volume distribution of the cooling air passing through the air flow distribution adjusting sheet 51 becomes substantially uniform, and almost the same environment as that when the dummy canisters are mounted on the empty slot. As specific means for equalizing the air volume distribution of the air passing through the air flow distribution adjusting sheet 51, the following methods, for example, are possible: (1) reducing the size of each of the ventilation holes 59 on the air flow distribution adjusting sheet 51 in an area closer to the canisters 21, and increasing the size of each of the ventilation holes 59 of the air flow distribution adjusting sheet 51 in an area farther from the canister 21; (2) decreasing the concentration of the ventilation holes 59 of the air flow distribution adjusting sheet 51 in an area closer to the canisters 21, and increasing the concentration of the ventilation holes 59 of the air flow distribution adjusting sheet 51 in an area farther from the canister 21. In the example shown in FIG. 9, a ventilation hole forming area 51 of the air flow distribution adjusting sheet 51a is approximately triangular in shape, and the number of ventilation holes 51 becomes smaller in the area closer to canisters 21. Reference number 51b indicates an area where no ventilation holes 59 are formed.

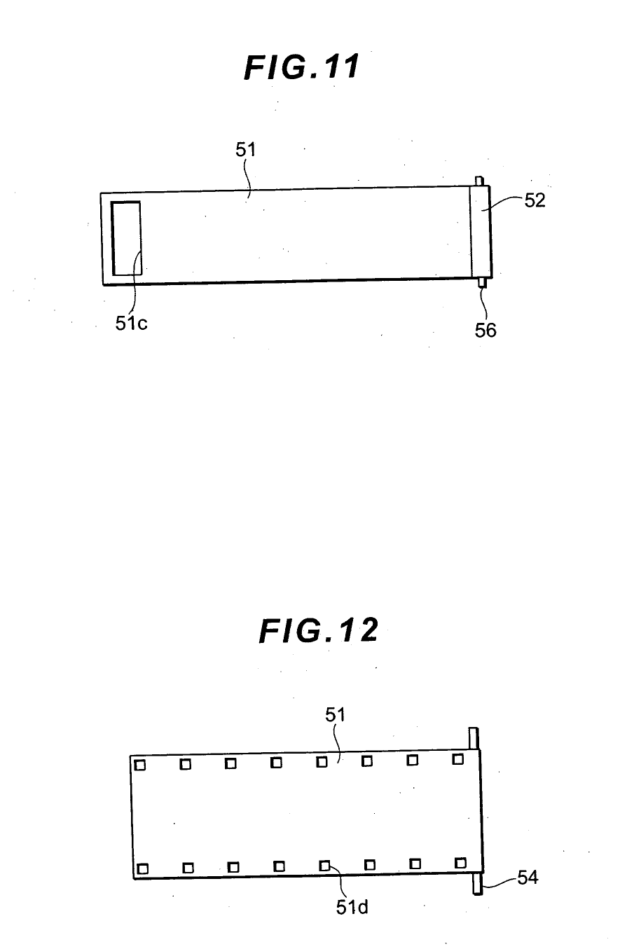

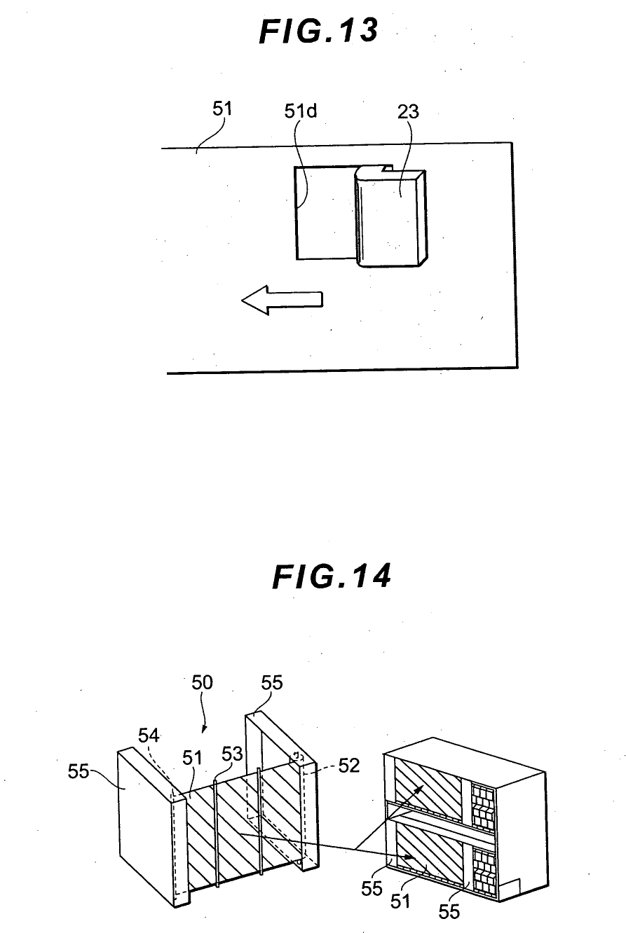

Next, a mechanism for preventing vibration of the air flow distribution adjusting sheet 51 is described with reference to FIGS. 10 to 13. If the air flow distribution adjusting sheet 51 vibrates due to wind pressure from the cooling air, noise may be generated or electromagnetic waves may leak from the disk array apparatus 10. When employing the vibration preventing pole 53 as a locking mechanism for fixing the air flow distribution adjusting sheet 51 to the HDD box 20 so as to prevent the above-described vibration, it is desirable to form a notch 22 on the canister mounting section of the HDD box 20 and have the vibration preventing pole 53 engage with the notch 22, thereby suppressing any vibration of the air flow distribution adjusting sheet 51. As for spacing between the vibration preventing poles 53, the vibration preventing poles 53 are preferably positioned every four canister slots. Moreover, the air flow distribution adjusting sheet 51 may be configured, as shown in FIG. 11, so that a locking hole 51c formed at the end of the air flow distribution adjusting sheet 51 is used to engage with a locking member (not shown) of the HDD box 20, thereby suppressing any vibration of the air flow distribution adjusting sheet 51 with its tensile force. Furthermore, the air flow distribution adjusting sheet 51 may be configured, as shown in FIG. 12, so that locking holes 51b formed along the edges of the air flow distribution adjusting sheet 51 are used to engage with locking members 23 of the HDD box 20 as shown in FIG. 13, thereby suppressing any vibration of the air volume adjusting sheet 51 with its tensile force. The locking holes 51d are desirably formed every two canister slots.

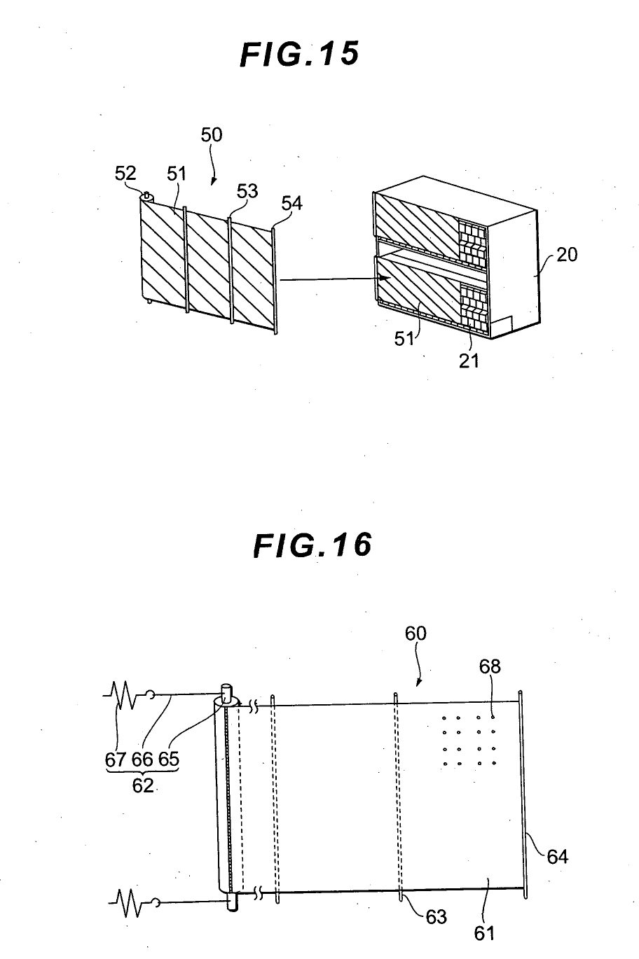

As an embodiment of mounting the air flow distribution adjusting mechanism 50 to the HDD box 20, the sheet expanded length adjusting mechanism 52 and the stopper 54 may be placed in the cases 55 respectively, which are then mounted on the HDD box 20 as shown in FIG. 14. Alternatively, as shown in FIG. 15, the sheet expanded length adjusting mechanism 52 and the stopper 54 may be attached directly to the HDD box 20 without using the cases 55.

With the disk array apparatus 10, there is a possibility that electromagnetic waves generated from various circuit elements in the logical boards 31 and power supply lines in the power supply box 40 may leak out and thereby affect the operation of other electronic devices. There is another possibility that electromagnetic waves leaking from other electronic devices placed near the disk array apparatus 10 may affect the operation of the disk array apparatus 10. Since the disk array apparatus 10 is required to demonstrate high data reliability, sufficient electromagnetic shielding properties are necessary. Accordingly, by employing, for example, a conductive sheet as the air flow distribution adjusting sheet 51, it is possible to cause an electromagnetic shielding effect on the front faces of the HDD box 20, logical board box 30, and power supply box 40, which do not conventionally have an electromagnetic shielding effect.

Furthermore, a connector is attached to the back board of the HDD box 20 as means for electrically connecting the canisters 21 with the HDD box 20. If the empty slot is left open, dust may accumulate on the connector and cause contact failure when the canisters 21 are mounted. Therefore, it is preferable to reduce the size of the ventilation hole 59 (e.g. to 1 mm or less in diameter) and increase the number of ventilation holes 59.

FIG. 16 shows the detailed configuration of an air flow distribution adjusting mechanism 60 according to another embodiment. The air flow distribution adjusting mechanism 60 includes an air flow distribution adjusting sheet 61, a sheet expanded length adjusting mechanism 62, a vibration preventing pole 63, and a stopper 64. The sheet expanded length adjusting mechanism 62 includes a shaft 65, a string 66, and a spring 67. The air flow distribution adjusting sheet 61 is adhesively attached to the surface of the shaft 65 with bonding means such as an adhesive agent. Also, one end of the string 66 is wound around the shaft 65, and the other end is joined to the spring 67. Because the spring 67 stretches via the string 66 when the air flow distribution adjusting sheet 61 is unwound, the restoring force acts on the air flow distribution adjusting sheet 61 depending on a rotation angle of the shaft 65. Supposing the diameter of the shaft 65 is R1 and that of the sheet expanded length adjusting mechanism 62 is R2, the following relationship is established R1:R2=(stretched length of the spring 67):(expanded length of the air flow distribution adjusting sheet 61)=α:1. When the value of α is smaller, a shorter stretched length of the spring is sufficient with respect to the expanded length of the air flow distribution adjusting sheet 61, and it is thereby possible to reduce the space around the spring 67. Incidentally, the air flow distribution adjusting sheet 61 has ventilation holes 68 distributed as shown in FIG. 9.

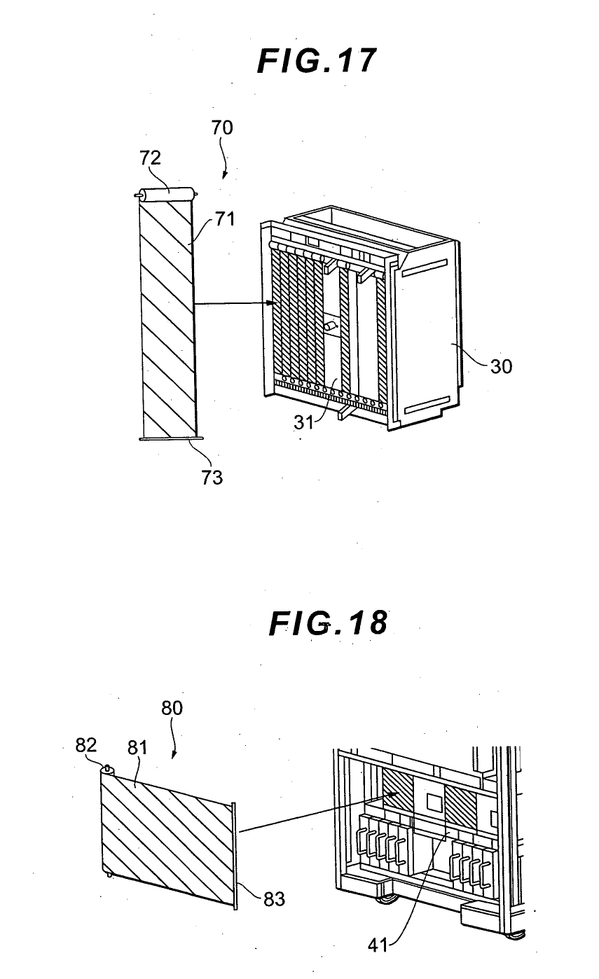

FIG. 17 shows the schematic configuration of an air flow distribution adjusting mechanism 70 to be mounted on an empty slot of the logical board box 30. The air flow distribution adjusting mechanism 70 includes an air flow distribution adjusting sheet 71, a sheet expanded length adjusting mechanism 72, and a stopper 73, and adjusts the distribution of the cooling air flowing inside the logical board box 30 to be almost equal to the distribution of the cooling air flowing inside the logical board box 30 carrying the logical board 31. The air flow distribution adjusting sheet 71 is almost the same size as that of the logical board 31. The detailed configuration of the air flow distribution adjusting mechanism 70 is similar to those of the above-described air flow distribution adjusting mechanisms 50 and 60. Although in the example shown in FIG. 17 the airflow distribution adjusting mechanism 70 covers only a single empty logical board slot, it may be designed to cover empty logical board slots.

FIG. 18 shows the schematic configuration of an air flow distribution adjusting mechanism 80 to be mounted in an empty slot of the power supply box 40. The air flow distribution adjusting mechanism includes an air flow distribution adjusting sheet 81, a sheet expanded length adjusting mechanism 82, and a stopper 83, and adjusts the distribution of the cooling air flowing inside the power supply box 40 to be almost equal to the distribution of the cooling air flowing inside the power supply box 40 mounted in the disk array apparatus 10. The size of air flow distribution adjusting sheet 81 is almost the same as that of the power supply box 40. The detailed configuration of the air flow distribution adjusting mechanism 81 is similar to those of the above-described air flow distribution adjusting mechanisms 50 and 60. Although in the example shown in FIG. 18 the air flow distribution adjusting mechanism 80 covers only an empty slot of a single power supply box 40, it may be designed to cover empty power supply box slots.

As described above, since the air flow distribution adjusting mechanisms 50 and 60 according to these embodiments are capable of entirely covering the HDD mounting slots for one rack, users should only prepare the air flow distribution adjusting mechanisms 50 and 60 for racks with empty slots. Accordingly, the dummy canisters required for the empty slots are no longer unnecessary and it is possible to realize low cost.

Furthermore, conventionally, 16 dummy canisters (width 30 mm×height 130 mm×depth 120 mm) were needed per one rack of the HDD box 20. With the air flow distribution adjusting mechanisms 50 and 60, however, one rack of HDD mounting slots can be entirely covered by expanding the air flow distribution adjusting mechanism 50 or 60, using the restoring force of the spiral springs. Additionally, when the air flow distribution adjusting sheet 51 or 61 is not in use, it can be wound around the sheet expanded length adjusting mechanism 52 or 53, thereby realizing compact storage (e.g. approximately φ 25 mm×height 125 mm). Accordingly, a small storage space is enough for the air flow distribution adjusting mechanisms 50 and 60 when not in use, and so it is possible to reduce management cost. Moreover, there is the added advantage of eliminating a customer's urge to dispose of the air flow distribution adjusting mechanisms 50 and 60 if left unused.

Furthermore, the air flow distribution adjusting mechanism 70 according to this embodiment contains sheet metal at a lower ratio than that of the conventional dummy cover for the empty slot of the logical board 31 made of sheet metal. Accordingly, it is possible to make the weight of the air flow distribution adjusting mechanism 70 lighter than conventional dummy cover. Therefore, it is possible to reduce deterioration of the earthquake resistance of the disk array apparatus 10.

Furthermore, the air flow distribution adjusting mechanisms 50 and 60 according to these embodiments are capable of removing the workload of mounting the dummy canisters when conducting a test, for example, before shipping products. Moreover, since an empty slot can be covered using the air flow distribution adjusting mechanisms 50 and 60 easily, users have an incentive to adjust the distribution of air flowing in the empty slots by using the air flow distribution adjusting mechanisms 50 and 60.

Furthermore, by employing a conductive sheet for the air flow distribution adjusting sheets 51, 61, 71, and 81 of the air flow distribution adjusting mechanisms 50, 60, 70, and 80 according to these embodiments, it is possible to enhance their shielding properties against electromagnetic waves leaking from the disk array apparatus 10.

We claim:

1. An air flow distribution adjusting mechanism for a disk array apparatus for adjusting a distribution of air flowing in a disk array apparatus having a plurality of canisters, the air flow distribution adjusting mechanism comprising:
an air flow distribution adjusting sheet for covering empty canister slots; and
a sheet expanded length adjusting mechanism for adjusting an expanded length of said air flow distribution adjusting sheet.

2. The air flow distribution adjusting mechanism for the disk array apparatus according to claim 1, wherein said air flow distribution adjusting sheet has ventilation holes so that the air flows through the ventilation holes in the air volume equivalent to that of the air flowing between the canisters mounted in the empty slots.

3. The air flow distribution adjusting mechanism for the disk array apparatus according to claim 2, wherein the ventilation holes are formed so that the distribution of the air passing through the air flow distribution adjusting sheet becomes smaller in the area closer to the canisters.

4. The air flow distribution adjusting mechanism for a disk array apparatus according to claim 1, further comprising a locking mechanism for suppressing vibration of said air flow distribution adjusting sheet.

5. An air flow distribution adjusting mechanism for a disk array apparatus according to claim 1, wherein said air flow distribution adjusting sheet is made of a conductive sheet.

6. An air flow distribution adjusting mechanism for a disk array apparatus for adjusting a volume of air flowing in a disk array apparatus having a plurality of logical boards, the air flow distribution adjusting mechanism comprising:
an air flow distribution adjusting sheet for covering empty logical board slots; and
a sheet expanded length adjusting mechanism for adjusting a expanded length of said air flow distribution adjusting sheet.

7. An air flow distribution adjusting mechanism for a disk array apparatus for adjusting a distribution of air flowing in a disk array apparatus having a plurality of power supply boxes, the air flow distribution adjusting mechanism comprising:
an air flow distribution adjusting sheet for covering empty power supply box slots; and
a sheet expanded length adjusting mechanism for adjusting a expanded length of said air flow distribution adjusting sheet.
